(19) United States
(12) Patent Application Publication
(10) Pub. No.: US 2026/0213729 A1
(43) Pub. Date: Jul. 23, 2026

(54) PIEZOELECTRIC DEVICE

(71) Applicant: Murata Manufacturing Co., Ltd., Nagaokakyo-shi (JP)

(72) Inventor: Takashi IWAMOTO, Nagaokakyo-shi (JP)

(21) Appl. No.: 19/572,026

(22) Filed: Mar. 19, 2026

Related U.S. Application Data
(63) Continuation of application No. PCT/JP2024/037059, filed on Oct. 17, 2024.

(30) Foreign Application Priority Data
Oct. 17, 2023 (JP) 2023-179092

(51) Int. Cl. H03H 9/17; H03H 3/02

(52) U.S. Cl. CPC H03H 9/178; H03H 3/02; H03H 9/173; H03H 2003/021

(57) ABSTRACT

A piezoelectric device includes a support including a support substrate, a piezoelectric layer with a thickness in a first direction and provided on a principal surface of the support, and a functional electrode on the principal surface of the piezoelectric layer. The piezoelectric layer includes first and second piezoelectric films that are laminated and each made of a single crystal of a same material. The first and second piezoelectric films have different polarization directions. The first and second piezoelectric films each include cleavage surfaces. At least one of the cleavage surfaces of the first piezoelectric film, and at least one of cleavage surfaces of the second piezoelectric film extend in intersecting directions in plan view in the first direction.

### CROSS REFERENCE TO RELATED APPLICATIONS

This application claims the benefit of priority to Japanese Patent Application No. 2023-179092 filed on Oct. 17, 2023 and is a Continuation Application of PCT Application No. PCT/JP2024/037059 filed on Oct. 17, 2024. The entire contents of each application are hereby incorporated herein by reference.

### BACKGROUND OF THE INVENTION

### 1. Field of the Invention

The present invention relates to piezoelectric devices.

### 2. Description of the Related Art

International Publication No. 2011/052551 discloses a piezoelectric device provided with a piezoelectric layer having a cleavage surface between upper and lower electrodes.

The piezoelectric device according to International Publication No. 2011/052551 has a possibility of developing cracks in a piezoelectric layer because the cleavage surface of the piezoelectric layer is vulnerable to stresses.

### SUMMARY OF THE INVENTION

Example embodiments of the present invention provide piezoelectric devices that each reduce or prevent cracks in a piezoelectric layer.

A piezoelectric device according to an example embodiment of the present invention includes a support including a support substrate, a piezoelectric layer with a thickness in a first direction and provided on a principal surface of the support, and a functional electrode on a principal surface of the piezoelectric layer, in which the piezoelectric layer includes a first piezoelectric film, and a second piezoelectric film laminated on the first piezoelectric film, the first piezoelectric film and the second piezoelectric film are each a single crystal made of a same material, the first piezoelectric film and the second piezoelectric film have different polarization directions, the first piezoelectric film and the second piezoelectric film each include cleavage surfaces, and at least one cleavage surface among the cleavage surfaces of the first piezoelectric film, and at least one cleavage surface among the cleavage surfaces of the second piezoelectric film extend in intersecting directions in plan view in the first direction.

According to example embodiments of the present invention, piezoelectric devices that each reduce or prevent cracks in a piezoelectric layer are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view showing an example of a piezoelectric device according to an example embodiment of the present invention.

FIG. 2 is a schematic sectional view taken along line II-II in FIG. 1.

FIG. 3 is a schematic plan view for explaining positions of cleavage surfaces of a first piezoelectric film according to an example embodiment of the present invention.

FIG. 4 is a schematic plan view for explaining positions of cleavage surfaces of a second piezoelectric film according to an example embodiment of the present invention.

FIG. 5 is a schematic sectional view taken along line V-V in FIG. 3.

FIG. 6 is a schematic sectional view for explaining polarization directions of the first piezoelectric film and the second piezoelectric film.

FIG. 7 is a schematic sectional view for explaining polarization directions of piezoelectric bodies according to a different example of a piezoelectric device according to an example embodiment of the present invention.

FIG. 8 is a process chart for explaining an example of a method for manufacturing a piezoelectric device according to an example embodiment of the present invention.

FIG. 9 is a diagram showing a relationship between a relative azimuthal angle δ and magnitude of load at the occurrence of cracks according to Example 1 of an example embodiment of the present invention.

FIG. 10 is a diagram showing a relation between the relative azimuthal angle δ and the magnitude of load at the occurrence of cracks according to Example 2 of an example embodiment of the present invention.

FIG. 11 is a diagram showing a relation between the relative azimuthal angle δ and the magnitude of load at the occurrence of cracks according to Example 3 of an example embodiment of the present invention.

FIG. 12 is a schematic plan view for explaining positions of cleavage surfaces according to Example 4 of an example embodiment of the present invention.

FIG. 13 is a schematic plan view for explaining positions of cleavage surfaces according to Example 5 of an example embodiment of the present invention.

### DETAILED DESCRIPTION OF THE EXAMPLE EMBODIMENTS

Example embodiments of the present invention will be described below in detail with reference to the drawings. The example embodiments do not limit the present invention. Here, the respective example embodiments described in the present disclosure are exemplary. Items common to the present example embodiment will be omitted in describing modifications as well as second and later example embodiments in which partial replacement or combination of elements are feasible among the different example embodiments, and only different features will be discussed. In particular, the same operations and advantageous effects due to the same or corresponding configurations will not be sequentially described in the respective example embodiments. Numerical values may include rounded off ranges.

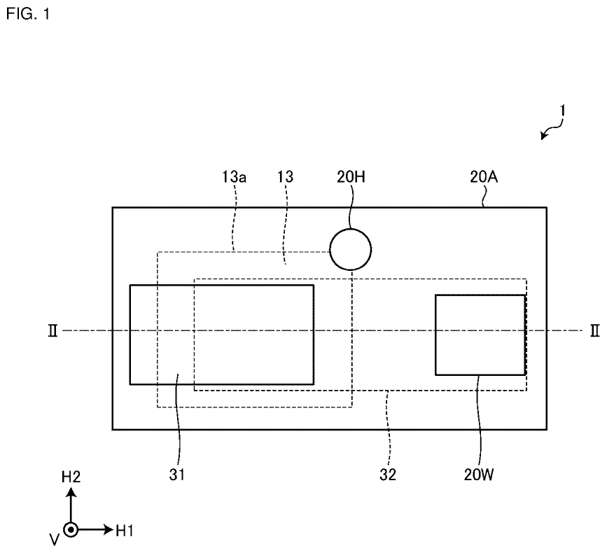

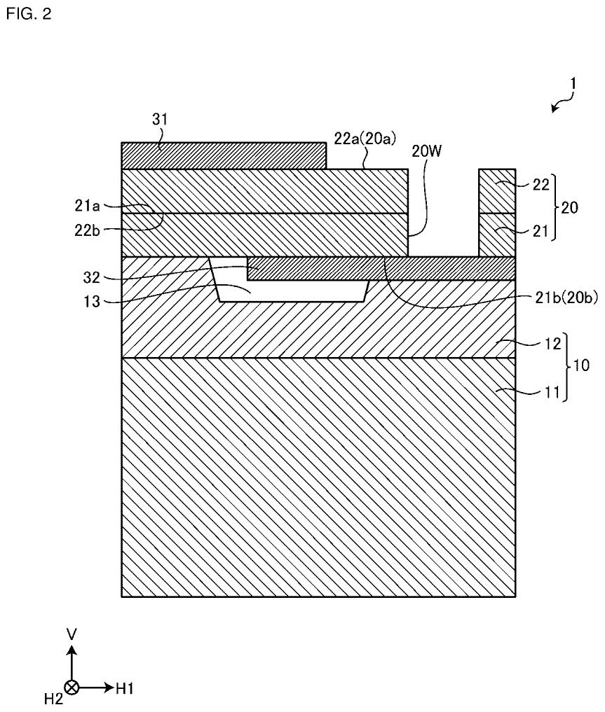

FIG. 1 is a schematic plan view showing an example of a piezoelectric device according to an example embodiment of the present invention. FIG. 2 is a schematic sectional view taken along line II-II in FIG. 1. A piezoelectric device 1 according to the present example embodiment includes a support 10, a piezoelectric layer 20, an upper electrode 31, and a lower electrode 32. The piezoelectric device 1 is an acoustic wave resonator that utilizes a bulk wave, that is to say, a bulk acoustic wave (BAW) resonator. In the example embodiment of FIG. 1, the piezoelectric device 1 is an acoustic wave filter resonator. In the following description, a thickness direction of the piezoelectric layer 20 will be explained as a V direction, a direction orthogonal or substantially orthogonal to the V direction will be explained as an H1 direction, and a direction orthogonal or substantially orthogonal to the V direction and to the H1 direction will be explained as an H2 direction. In the present disclosure, the V direction is an example of a “first direction”.

The piezoelectric layer 20 is a thin film having the thickness in the V direction. The piezoelectric layer 20 includes an upper surface 20a and a lower surface 20b. The film thickness of the piezoelectric layer 20 is not limited to a particular value, but is preferably equal to or less than about 1 μm, for example. This can achieve favorable resonance characteristics.

The piezoelectric layer 20 includes a first piezoelectric film 21 and a second piezoelectric film 22. The second piezoelectric film 22 is laminated on the first piezoelectric film 21 in the V direction, thus defining a multilayer body. The first piezoelectric film 21 includes a first principal surface 21a and a second principal surface 21b. The second piezoelectric film 22 includes a third principal surface 22a and a fourth principal surface 22b. In the example embodiment of FIG. 2, the third principal surface 22a of the second piezoelectric film 22 corresponds to the upper surface 20a of the piezoelectric layer 20. The second principal surface 21b of the first piezoelectric film 21 corresponds to the lower surface 20b of the piezoelectric layer 20. Meanwhile, the multilayer body is formed by joining the first principal surface 21a of the first piezoelectric film 21 to the fourth principal surface 22b of the second piezoelectric film 22 in such a way as to be opposed to each other. Thus, a strength of the piezoelectric layer 20 can be improved. Moreover, it is possible to further reduce or prevent unwanted resonance of the piezoelectric device 1 and to further reduce or prevent deterioration in resonance characteristics due to improvements in driving force depending on how to combine polarization directions. Details of the first piezoelectric film 21 and the second piezoelectric film 22 will be described later.

The piezoelectric layer 20 includes a through hole 20H that communicates with a void portion 13. The through hole 20H is located at a position overlapping the void portion 13 in plan view in the V direction. In the example embodiment of FIG. 1, the through hole 20H is located at a position overlapping a boundary 13a of the void portion 13 to be described later. However, without limitation to the foregoing, the through hole 20H may extend through the upper electrode 31 and the lower electrode 32. The through hole 20H only needs to be located at such a position that overlaps the void portion 13.

In the example embodiment of FIG. 2, the piezoelectric layer 20 includes an open window 20W. The open window 20W is provided at a position overlapping the lower electrode 32 and not overlapping the void portion 13. In this way, the lower electrode 32 is exposed so that wiring can be extracted to the upper surface 20a side of the piezoelectric layer 20. The shape of the open window 20W shown in FIG. 2 is merely an example and the shape is not limited thereto.

The upper electrode 31 is provided on the upper surface 20a of the piezoelectric layer 20. The lower electrode 32 is provided on the lower surface 20b of the piezoelectric layer 20. The upper electrode 31 and the lower electrode 32 are made of, for example, a metal or an alloy of aluminum (Al), platinum (Pt), copper (Cu), tungsten (W), molybdenum (Mo), or the like. Here, the upper electrode 31 and the lower electrode 32 may include an adhesive layer made of, for example, titanium (Ti), nickel-chromium alloy (NiCr), or the like.

As shown in FIG. 1, the upper electrode 31 and the lower electrode 32 are each strip-shaped electrodes, for example. In plan view in the V direction, a portion of the upper electrode 31 overlaps a portion of the lower electrode 32. In other words, the piezoelectric layer 20 includes a region sandwiched between the upper electrode 31 and the lower electrode 32. Accordingly, a bulk wave is propagated in a region between the upper electrode 31 and the lower electrode 32. Here, the shapes of the upper electrode 31 and the lower electrode 32 are mere examples, and the shapes are not limited thereto. In the following description, the region where the upper electrode 31 overlaps the lower electrode 32 in plan view in the V direction may be explained as an excitation region in some cases.

The support 10 is opposed to the lower surface 20b of the piezoelectric layer 20. In the present example embodiment, the support 10 includes a support substrate 11 and an intermediate layer 12. The support substrate 11 is a substrate made of, for example, silicon (Si), quartz crystal, or the like. The intermediate layer 12 is provided on the piezoelectric layer 20 side of the support substrate 11. The intermediate layer 12 is includes an insulating body such as silicon oxide, for example. The support 10 includes the void portion 13. In the example embodiment of FIG. 2, the void portion 13 is a space inside a recess provided on the piezoelectric layer 20 side of the intermediate layer 12. The void portion 13 overlaps the excitation region in plan view in the V direction. Accordingly, an energy loss of the bulk wave from the piezoelectric device 1 is reduced at the time of excitation, so that favorable resonance characteristics are achieved. Here, the support 10 may include a Bragg reflector instead of being provided with the void portion 13. That is to say, the piezoelectric device according to the present example embodiment may be a solid mounted resonator (SMR).

In the following description, the boundary 13a between the region overlapping the void portion 13 and the region not overlapping the void portion 13 in plan view in the V direction will be described as the boundary 13a of the void portion. In the example embodiment of FIG. 1, the region overlapping the void portion 13 in plan view in the V direction has a rectangular or substantially orthogonal shape. However, this is a mere example and the region may have a different shape such as a circular shape, for example.

The first piezoelectric film 21 and the second piezoelectric film 22 will be described below in detail. In the following description, the first piezoelectric film 21 and the second piezoelectric film 22 may be explained collectively as the piezoelectric films in some cases. In the present disclosure, the term “intersection” means a state where an angle is equal to or greater than 1°, for example.

In the present example embodiment, the first piezoelectric film 21 and the second piezoelectric film 22 are made of the same piezoelectric single-crystal material. In the present disclosure, the state of being made of the same material means a state of being made of substances expressed by the same empirical formula. In a case where the first piezoelectric film 21 and the second piezoelectric film 22 are made of different materials, there is a possibility of a failure to sufficiently reduce or prevent cracks in the piezoelectric layer 20 due to effects of difference in material physical properties. By providing the piezoelectric body including the first piezoelectric film 21 and the second piezoelectric film 22 made of the same material, the effects of differences in material physical properties can be reduced or prevented, so that cracks in the piezoelectric layer 20 can be reduced or prevented.

In the present example embodiment, a piezoelectric body including each of the first piezoelectric film 21 and the second piezoelectric film 22 is a substrate made of a single crystal. The piezoelectric body of each of the first piezoelectric film 21 and the second piezoelectric film 22 is preferably made of lithium niobate (LiNbO₃) or lithium tantalate (LiTaO₃), for example. In this way, the piezoelectric device 1 can operate as a bulk wave resonator having suitable acoustic wave filter characteristics.

The first piezoelectric film 21 and the second piezoelectric film 22 include cleavage surfaces. That is to say, directions in which cracks due to stress are likely to develop (directions of the cleavage surfaces) are present in the first piezoelectric film 21 and the second piezoelectric film 22. The directions of cleavage surfaces are intrinsic directions due to the material of the piezoelectric film and to a crystal orientation of the piezoelectric film. Specific examples of the directions of the cleavage surfaces corresponding to the piezoelectric material of the first piezoelectric film 21 and the second piezoelectric film 22 and to the crystal orientations of the piezoelectric films will be discussed later in the description of examples. Since the direction of the cleavage surface is intrinsic to a composition of a piezoelectric single crystal body, the direction of the cleavage surface can be specified by determining the crystal orientation of the piezoelectric single crystal body by X-ray diffraction, for example.

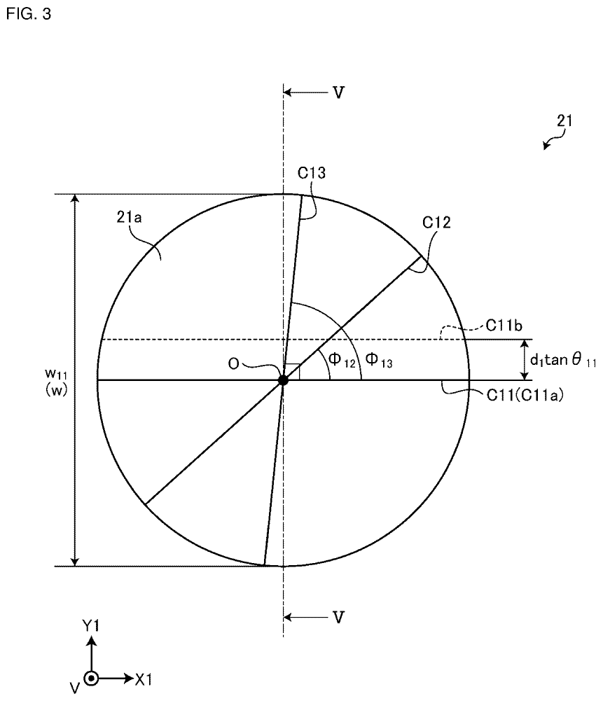

Here, since the cleavage surface originates from the crystal structure of the piezoelectric body, multiple cleavage surfaces are present which are parallel or substantially parallel to one cleavage surface of each of the first piezoelectric film 21 and the second piezoelectric film 22. In FIGS. 3 to 5, 12, and 13, to be used in the following explanations, illustration of the cleavage surfaces parallel or substantially parallel to one cleavage surface will be omitted and only the cleavage surface will be representatively described. To be more precise, among the cleavage surfaces, only the cleavage surface of which intersection line with the first principal surface 21a or the third principal surface 22a passes through a geometric center O of the void portion 13 in plan view in the V direction will be illustrated and described. Moreover, in the relevant drawing, the shape of the void portion 13 in plan view in the V direction is assumed to be circular, and the piezoelectric layer 20 as well as the first piezoelectric film 21 or the second piezoelectric film 22 in the region overlapping the void portion 13 in plan view in the V direction will be illustrated while omitting the through hole 20H.

FIG. 3 is a schematic plan view for explaining positions of the cleavage surfaces of the first piezoelectric film according to the present example embodiment. In the example embodiment of FIG. 3, the first piezoelectric film 21 includes cleavage surfaces C11 to C13 extending in different directions from one another. The first cleavage surface C11 is located on a counterclockwise side at the largest angle among angles formed with the cleavage surfaces C11 to C13 of the first piezoelectric film 21 extending in the different directions in plan view in the first direction. The second cleavage surface C12 is a cleavage surface intersecting with the first cleavage surface C11, which is a cleavage surface among the cleavage surfaces of the first piezoelectric film 21 located on the counterclockwise side of the first cleavage surface C11 with the smallest angle formed with the first cleavage surface C11. The third cleavage surface C13 is a cleavage surface intersecting with the first cleavage surface C11 and the second cleavage surface C12, which is a cleavage surface among the cleavage surfaces of the first piezoelectric film 21 located on the counterclockwise side of the second cleavage surface C12 with the smallest angle formed with the second cleavage surface C12.

In the following description, a direction perpendicular or substantially perpendicular to the V direction and parallel or substantially parallel to a direction in which the first cleavage surface C11 extends will be defined as X1 direction, and a direction perpendicular or substantially perpendicular to the X1 direction and the V direction will be defined as Y1 direction. Although the X1 direction and the H1 direction are different directions, these directions may be the same directions instead.

As shown in FIG. 3, in the following description, the magnitude of the angle between the first cleavage surface C11 and the second cleavage surface C12 will be defined as an azimuthal angle φ₁₂ of the second cleavage surface C12, and magnitude of the angle between the first cleavage surface C11 and the third cleavage surface C13 will be defined as an azimuthal angle φ13 of the third cleavage surface C13.

Meanwhile, the magnitude of the angles between the V direction and the cleavage surfaces C11, C12, and C13 will be described as inclination angles θ₁₁, θ₁₂, and θ₁₃ of the cleavage surfaces C11, C12, and C13, respectively. In the present disclosure, the magnitude of the angle between the V direction and the cleavage surface represents an angle obtained by subtracting magnitude of an angle between the V direction and a normal vector of the cleavage surface from the magnitude of a right angle (90°).

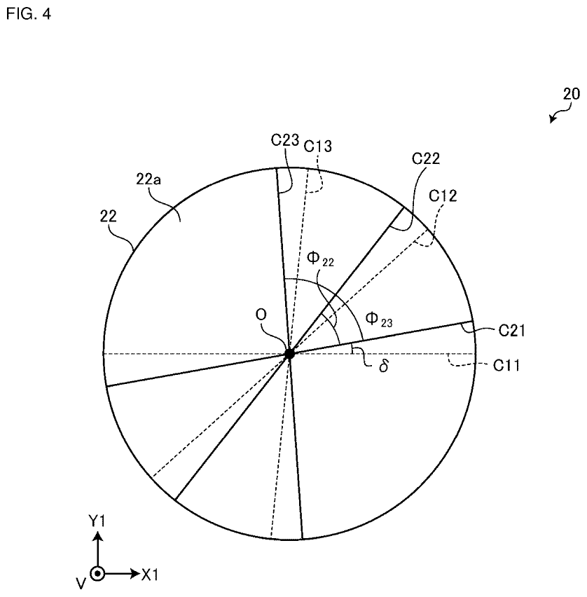

FIG. 4 is a schematic plan view for explaining positions of the cleavage surfaces of the second piezoelectric film according to the present example embodiment. In the example embodiment of FIG. 4, the second piezoelectric film 22 includes cleavage surfaces C21 to C23 extending in different directions from one another. The first cleavage surface C21 is a cleavage surface located on a counterclockwise side at the largest angle among angles formed by the cleavage surfaces C21 to C23 of the second piezoelectric film 22 extending in the different directions in plan view in the first direction. The second cleavage surface C22 is a cleavage surface intersecting with the first cleavage surface C21, which is a cleavage surface among the cleavage surfaces of the second piezoelectric film 22 located on the counterclockwise side of the first cleavage surface C21 with the smallest angle formed with the first cleavage surface C21. The third cleavage surface C23 is a cleavage surface intersecting with the first cleavage surface C21 and the second cleavage surface C22, which is a cleavage surface among the cleavage surfaces of the second piezoelectric film 22 located on the counterclockwise side of the second cleavage surface C22 with the smallest angle formed with the second cleavage surface C22.

As shown in FIG. 4, in the following description, the magnitude of the angle between the first cleavage surface C21 and the second cleavage surface C22 will be defined as an azimuthal angle φ₂₂ of the second cleavage surface C22, and the magnitude of the angle between the first cleavage surface C21 and the third cleavage surface C23 will be defined as an azimuthal angle φ₂₃ of the third cleavage surface C23. Meanwhile, the magnitude of an angle between the first cleavage surface C11 of the first piezoelectric film 21 and the first cleavage surface C21 of the second piezoelectric film 22 will be explained as a relative azimuthal angle d.

Meanwhile, magnitude of the angles between the V direction and the cleavage surfaces C21, C22, and C23 will be described as inclination angles θ₂₁, θ₂₂, and θ₂₃ of the cleavage surfaces C21, C22, and C23, respectively.

In the present example embodiment, at least one cleavage surface among the cleavage surfaces C11 to C13 of the first piezoelectric film 21 and at least one cleavage surface among the cleavage surfaces C21 to C23 of the second piezoelectric film 22 extend in intersecting directions in plan view in the V direction. Accordingly, it is possible to reduce or prevent cracks in the piezoelectric layer 20 attributable to the cleavage surfaces.

Meanwhile, the cleavage surface having the smallest angle with the V direction among the cleavage surfaces C11 to C13 of the first piezoelectric film 21, and the cleavage surface having the smallest angle with the V direction among the cleavage surfaces C21 to C23 of the second piezoelectric film 22 preferably extend in the intersecting directions in plan view in the V direction. Accordingly, it is possible to reduce or prevent cracks in the piezoelectric layer 20 attributable to the cleavage surfaces more appropriately.

In the meantime, at least one cleavage surface among the cleavage surfaces C11 to C13 of the first piezoelectric film 21 preferably extends in the same or substantially the same direction as a bisector of an angle between two cleavage surfaces among the cleavage surfaces C21 to C23 of the second piezoelectric film 22 intersecting with each other in plan view in the first direction, and at least one cleavage surface among the cleavage surfaces C21 to C23 of the second piezoelectric film 22 preferably extends in the same or substantially the same direction as a bisector of an angle between two cleavage surfaces among the cleavage surfaces C11 to C13 of the first piezoelectric film 21 intersecting with each other in plan view in the first direction. Accordingly, it is possible to reduce or prevent cracks in the piezoelectric layer 20 attributable to the cleavage surfaces more appropriately.

Meanwhile, all of the cleavage surfaces C11 to C13 of the first piezoelectric film 21 and all of the cleavage surfaces C21 to C23 of the second piezoelectric film 22 preferably extend in the intersecting directions in plan view in the V direction. That is to say, every one of the cleavage surfaces C11 to C13 of the first piezoelectric film 21 preferably extends in the direction intersecting with every one of the cleavage surfaces C21 to C23 of the second piezoelectric film 22. In this case, it is possible to reduce or prevent cracks in the piezoelectric layer 20 attributable to the cleavage surfaces more appropriately.

In this case, the magnitude of the smallest angle between one of the cleavage surfaces C11 to C13 of the first piezoelectric film 21 and one of the cleavage surfaces C21 to C23 of the second piezoelectric film 22 is, for example, preferably equal to or greater than about 3°, or more preferably equal to or greater than about 12.5°. Accordingly, it is possible to reduce or prevent cracks in the piezoelectric layer 20 attributable to the cleavage surfaces more appropriately. In the following description, the magnitude of the smallest angle between one of the cleavage surfaces C11 to C13 of the first piezoelectric film 21 and one of the cleavage surfaces C21 to C23 of the second piezoelectric film 22 may be explained as a minimum azimuthal angle in some cases.

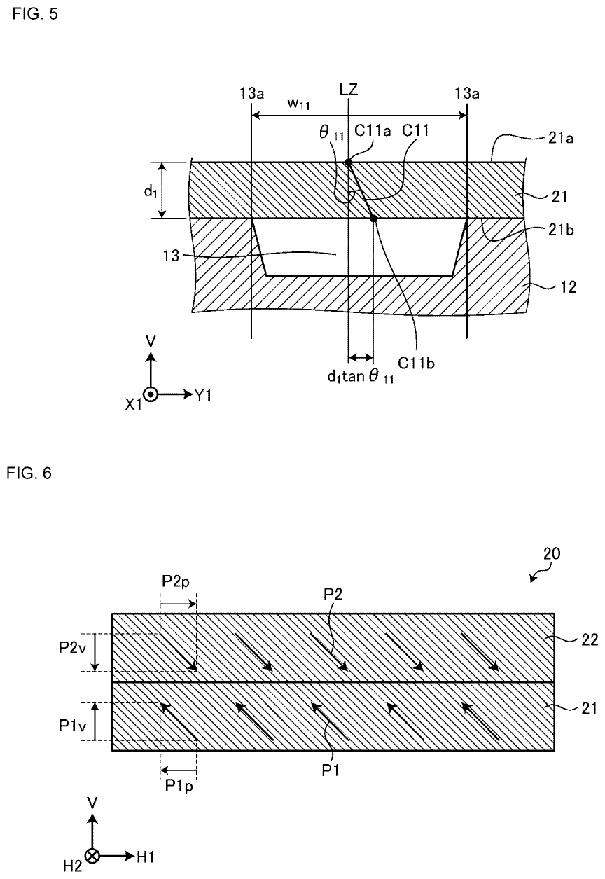

FIG. 5 is a schematic sectional view taken along line V-V in FIG. 3. FIG. 5 is a sectional view taken along a direction perpendicular or substantially perpendicular to an intersection line C11a of the first cleavage surface C11 of the first piezoelectric film 21 and the first principal surface 21a. In the example embodiments of FIGS. 3 and 5, the intersection line C11a of the first cleavage surface C11 and the first principal surface 21a, and an intersection line C11b of the first cleavage surface C11 and the second principal surface 21b overlap the void portion 13 in plan view in the V direction. These cleavage surfaces are prone to development of cracks because there is a region from the first principal surface 21a to the second principal surface 21b where the V direction side is not supported by the support 10. Similarly, regarding the second piezoelectric film 22, cleavage surfaces in which an intersection line of the cleavage surface and the third principal surface 22a as well as an intersection line of the cleavage surface and the fourth principal surface 22b overlap the void portion 13 in plan view in the V direction are prone to development of cracks because there is a region from the third principal surface 22a to the fourth principal surface 22b where the V direction side is not supported by the support 10.

Accordingly, the cleavage surface in which the intersection line with the first principal surface 21a and the intersection line with the second principal surface 21b pass through the region overlapping the void portion 13 in plan view in the V direction among the cleavage surfaces of the first piezoelectric film 21, and the cleavage surface in which the intersection line with the third principal surface 22a and the intersection line with the fourth principal surface 22b pass through the region overlapping the void portion 13 in plan view in the V direction among the cleavage surfaces of the second piezoelectric film 22 preferably extend in the intersecting directions. Thus, it is possible to reduce or prevent cracks in the piezoelectric layer 20 attributable to the cleavage surfaces that are prone to development of cracks.

In the following description, a cleavage surface among the cleavage surfaces of the first piezoelectric film 21 and the second piezoelectric film 22, which is particularly prone to development of cracks will be explained as a specific cleavage surface. On a specific cleavage surface of the first piezoelectric film 21, an intersection line of the specific cleavage surface and the first principal surface 21a and an intersection line of the specific cleavage surface and the second principal surface 21b pass through the region overlapping the void portion 13 in plan view in the V direction. Meanwhile, on a specific cleavage surface of the second piezoelectric film 22, an intersection line of the specific cleavage surface and the third principal surface 22a and an intersection line of the specific cleavage surface and the fourth principal surface 22b pass through the region overlapping the void portion 13 in plan view in the V direction.

Here, conditions of the presence of the specific cleavage surface will be described using FIGS. 3 and 5. In the following description, a thickness of the first piezoelectric film 21 will be defined as di. Meanwhile, in plan view in the V direction, a maximum width of the void portion 13 in terms of a direction perpendicular or substantially perpendicular to the intersection line C11a of the first cleavage surface C11 and the first principal surface 21a of the first piezoelectric film 21 will be explained as w₁₁. In the present example embodiment, the void portion 13 is circular or substantially circular in plan view in the V direction. Accordingly, the width Wii is equal or substantially equal to a diameter w of the void portion 13. Although the first piezoelectric film 21 will be discussed as an example in the following description, the same applies to the second piezoelectric film 22 and explanations thereof will be omitted.

As shown in FIGS. 3 and 5, the specific cleavage surface (the first cleavage surface C11) needs to satisfy a condition that a portion of the intersection line (the intersection line C11a) with the first principal surface 21a and a portion of the intersection line (the intersection line C11b) with the second principal surface 21b are present in a region with the width w₁₁ surrounded by the boundary 13a of the void portion 13. The inclination angle θ₁₁ of the specific cleavage surface therefore satisfies a condition of formula (1):

$$tan {θ}_{11} \leq {w}_{11} / {d}_{1} . \qquad ( 1 )$$

Accordingly, the presence of the cleavage surface satisfying the above-described formula (1) regarding the inclination angle θ₁₁ is equivalent to the presence of the specific cleavage surface parallel or substantially parallel to the relevant cleavage surface.

As described above, if the cleavage surface among the cleavage surfaces of the first piezoelectric film 21 which satisfies the relationship of the above-described formula (1) and the cleavage surface among the cleavage surfaces of the second piezoelectric film which satisfies the relation of the above-described formula (1) extend in the intersecting directions, then it can be said that the specific cleavage surface of the first piezoelectric film 21 and the specific cleavage surface of the second piezoelectric film 22 extend in the intersecting directions.

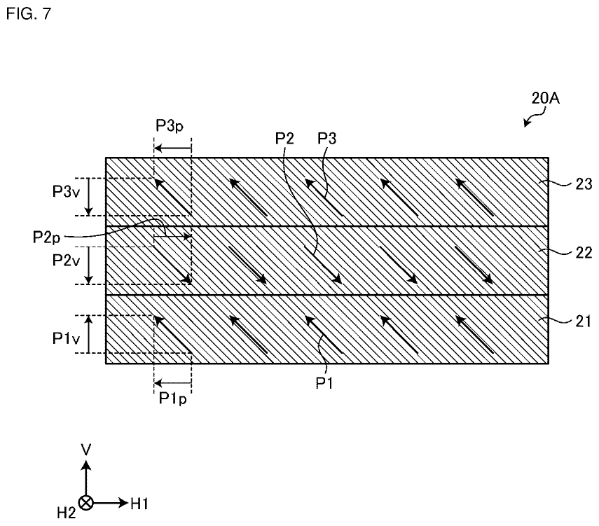

FIG. 6 is a schematic sectional view for explaining polarization directions of the first piezoelectric film and the second piezoelectric film. In FIG. 6, arrows P1 and P2 indicate polarization directions of the first piezoelectric film 21 and the second piezoelectric film 22, respectively. In the following description, a component in the V direction of the arrow P1 will be explained as a component P1v, a component in the direction perpendicular or substantially perpendicular to the V direction of the arrow P1 will be explained as a component P1p, a component in the V direction of the arrow P2 will be explained as a component P2V, and a component in the direction perpendicular or substantially perpendicular to the V direction of the arrow P2 will be explained as a component P2p.

In the present example embodiment, the first piezoelectric film 21 and the second piezoelectric film 22 have different polarization directions. Here, the different polarization directions mean a state in which polarization directions are not identical. Depending on a combination of the polarization directions of the respective piezoelectric films, it is possible to obtain bulk wave resonance characteristics that allow effective passage of a desired band, thus reducing or preventing unwanted resonance in filter characteristics.

In the present example embodiment, the component P1v of the V direction in the direction of polarization of the first piezoelectric film 21 and the component P2v of the V direction in the direction of polarization of the second piezoelectric film 22 have opposite directions to each other. Here, when the thicknesses of the first piezoelectric film 21 and the second piezoelectric film 22 are equal or substantially equal, the two layers of the piezoelectric films resonate at the same frequency concerning resonance of the bulk wave in the thickness direction. Accordingly, it is possible to provide a filter that can obtain favorable filter characteristics by configuring the filter by combining resonators including the piezoelectric films according to the present example embodiment. The polarization directions of the first piezoelectric film 21 and the second piezoelectric film 22 can be observed in accordance with scanning probe microscopy (SPM), for example. Specifically, regions having different polarization directions in an image of cross-sections of the first piezoelectric film 21 and the second piezoelectric film 22 taken along the V direction and observed with a piezo-response microscope (PRM) appear as regions with different colors. Then, the direction of polarization of the first piezoelectric film 21 and the direction of polarization of the second piezoelectric film 22 can be identified by determining the crystal orientations in accordance with a crystal structure analysis by the X-ray diffraction of the first piezoelectric film 21 and the second piezoelectric film 22.

In the present example embodiment, the component P1p perpendicular or substantially perpendicular to the V direction in the direction of polarization of the first piezoelectric film 21 and the component P2p perpendicular or substantially perpendicular to the V direction in the direction of polarization of the second piezoelectric film 22 have opposite directions from each other. Accordingly, depending on a combination of the polarization directions of the respective piezoelectric films, it is possible to obtain bulk wave resonance characteristics that allow effective passage of a desired band, thus reducing or preventing unwanted resonance in the filter characteristics.

Although one example of the piezoelectric device according to the present example embodiment has been described above, the piezoelectric device according to the present example embodiment is not limited to the above-described example.

For example, the first piezoelectric film and the second piezoelectric film may each be a substrate made of a single crystal of potassium niobate (KNbO₃). Since KNbO₃ has a larger electromechanical coupling coefficient as compared to those of LiNbO₃ and LiTaO₃, a filter having a wider passband can be provided by forming the filter while combining resonators that adopt KNbO₃ as the piezoelectric films. Here, the first piezoelectric film and the second piezoelectric film each made of the single crystal of KNbO₃ include the cleavage surfaces. Nonetheless, it is possible to reduce or prevent cracks in the piezoelectric layers by configuring the cleavage surfaces of the first piezoelectric film and the second piezoelectric film in the same or substantially the same configurations as those described above.

FIG. 7 is a schematic sectional view for explaining polarization directions of piezoelectric bodies according to a different example of a piezoelectric device according to an example embodiment of the present invention. In FIG. 7, arrows P1, P2, and P3 indicate polarization directions of the first piezoelectric film 21, the second piezoelectric film 22, and a third piezoelectric film 23, respectively. Here, as with the arrows P1 and P2, a component in the V direction of the arrow P3 will be explained as a component P3v and a component perpendicular or substantially perpendicular to the V direction of the arrow P3 will be explained as a component P3p. As shown in FIG. 7, a piezoelectric layer 20A may be a multilayer body including three or more layers of piezoelectric films, for example. In the example embodiment of FIG. 7, the piezoelectric layer 20A includes the first piezoelectric film 21, the second piezoelectric film 22, and the third piezoelectric film 23. In this case, a positional relationship and the polarization directions of the cleavage surfaces of the piezoelectric films located adjacent to each other in the lamination direction of the piezoelectric films are preferably the same or substantially the same as the relationship between the first piezoelectric film 21 and the second piezoelectric film 22 described above. In the example embodiment of FIG. 7, the component P1p perpendicular or substantially perpendicular to the V direction in the direction of polarization of the first piezoelectric film 21 as well as the component P3p perpendicular or substantially perpendicular to the V direction in the direction of polarization of the third piezoelectric film 23 have directions opposite to that of the component P2p perpendicular or substantially perpendicular to the V direction in the direction of polarization of the second piezoelectric film 22. Accordingly, depending on a combination of the polarization directions of the respective piezoelectric films, it is possible to obtain bulk wave resonance characteristics that allow effective passage of a desired band, thus reducing or preventing unwanted resonance in light of the filter characteristics.

As described above, the piezoelectric device according to the present example embodiment includes the support including the support substrate, the piezoelectric layer having the thickness in the first direction and being provided on the principal surface of the support, and the functional electrode provided on the principal surface of the piezoelectric layer. The piezoelectric layer includes the first piezoelectric film, and the second piezoelectric film laminated on the first piezoelectric film. The first piezoelectric film and the second piezoelectric film are each the single crystal made of the same material. The first piezoelectric film and the second piezoelectric film have the different polarization directions. The first piezoelectric film and the second piezoelectric film include the cleavage surfaces. At least one cleavage surface among the cleavage surfaces of the first piezoelectric film and at least one cleavage surface among the cleavage surfaces of the second piezoelectric film extend in the intersecting directions in plan view in the first direction. Accordingly, it is possible to reduce or prevent cracks in the piezoelectric layer, to obtain the bulk wave resonance characteristics that allow effective passage of the desired band, and to reduce or prevent unwanted resonance in the filter characteristics depending on the combination of the polarization directions of the respective piezoelectric films.

Preferably, for example, the cleavage surface among the cleavage surfaces of the first piezoelectric film which forms the smallest angle with the first direction and the cleavage surface among the cleavage surfaces of the second piezoelectric film which forms the smallest angle with the first direction extend in the intersecting directions in plan view in the first direction. Accordingly, it is possible to reduce or prevent cracks in the piezoelectric layer more appropriately.

Preferably, for example, the support includes the void portion at the position at least partially overlapping the piezoelectric layer in plan view in the first direction. Accordingly, the energy loss of the bulk wave from the piezoelectric device 1 is reduced at the time of excitation, so that favorable resonance characteristics are available.

More preferably, for example, the first piezoelectric film includes the first principal surface and the second principal surface. The second piezoelectric film includes the third principal surface and the fourth principal surface. At least one cleavage surface among the cleavage surfaces in which the intersection line with the first principal surface and the intersection line with the second principal surface pass through the region overlapping the void portion in plan view in the first direction among the cleavage surfaces of the first piezoelectric film, and at least one cleavage surface among the cleavage surfaces in which the intersection line with the third principal surface and the intersection line with the fourth principal surface pass through the region overlapping the void portion in plan view in the first direction among the cleavage surfaces of the second piezoelectric film extend in the intersecting directions. Accordingly, it is possible to reduce or prevent cracks in the piezoelectric layer more appropriately.

Preferably, for example, at least one cleavage surface among the cleavage surfaces of the first piezoelectric film extends in the same or substantially the same direction as the bisector of the angle between two cleavage surfaces of the second piezoelectric film intersecting with each other in plan view in the first direction. At least one cleavage surface among the cleavage surfaces of the second piezoelectric film extends in the same or substantially the same direction as the bisector of the angle between two cleavage surfaces of the first piezoelectric film intersecting with each other in plan view in the first direction. Accordingly, it is possible to reduce or prevent cracks in the piezoelectric layer more appropriately.

Preferably, for example, all of the cleavage surfaces of the first piezoelectric film and all of the cleavage surfaces of the second piezoelectric film extend in the intersecting directions in plan view in the first direction. Accordingly, it is possible to reduce or prevent cracks in the piezoelectric layer more appropriately.

More preferably, for example, the magnitude of the smallest angle between the cleavage surface of the first piezoelectric film and the cleavage surface of the second piezoelectric film is equal to or greater than about 3°. Accordingly, it is possible to reduce or prevent cracks in the piezoelectric layer even more appropriately.

Even more preferably, for example, the magnitude of the smallest angle between the cleavage surface of the first piezoelectric film and the cleavage surface of the second piezoelectric film is equal to or greater than about 12.5°. Accordingly, it is possible to reduce or prevent cracks in the piezoelectric layer even more appropriately.

Preferably, for example, the first piezoelectric film and the second piezoelectric film are made of LiTaO₃, LiNbO₃, or KNbO₃, for example. Accordingly, the piezoelectric device 1 can operate as the bulk wave resonator having suitable acoustic wave filter characteristics.

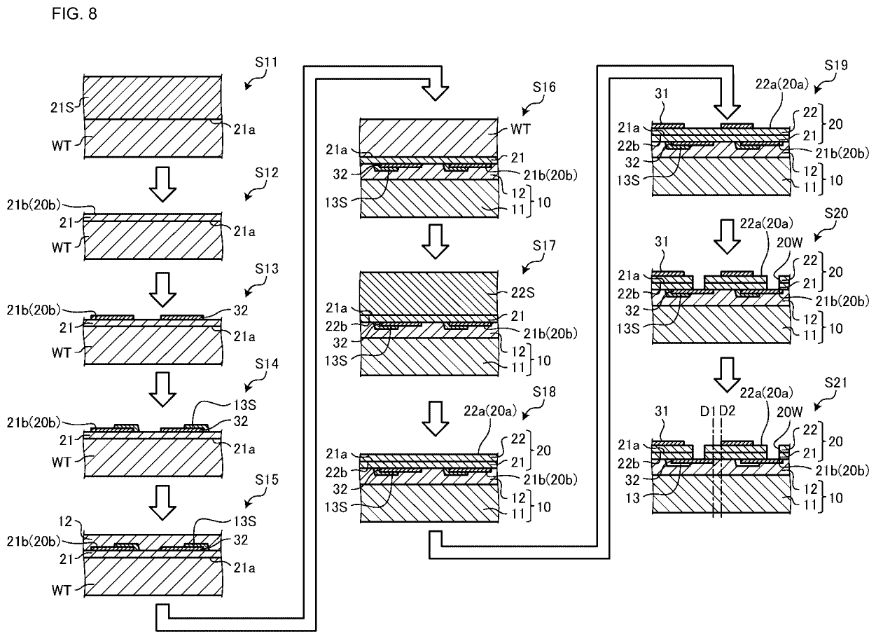

An example of a manufacturing method of a piezoelectric device according to the present example embodiment will be described below. FIG. 8 is a process chart for explaining the example of the method for manufacturing a piezoelectric device according to the present example embodiment. As shown in FIG. 8, the method for manufacturing a piezoelectric device according to the present example embodiment includes a first piezoelectric material substrate bonding process (step S11), a first piezoelectric material substrate thinning process (step S12), a lower electrode forming process (step S13), a sacrificial layer forming process (step S14), an intermediate layer forming process (step S15), a joining process (step S16), a second piezoelectric material substrate bonding process (step S17), a second piezoelectric material substrate thinning process (step S18), an upper electrode forming process (step S19), a piezoelectric layer window opening process (step S20), and a void portion forming process (step S21).

In the first piezoelectric material substrate bonding process (step S11), a first piezoelectric material substrate 21S being the unprocessed first piezoelectric film 21 is bonded to a principal surface of a transfer substrate WT.

In the first piezoelectric material substrate thinning process (step S12), the first piezoelectric material substrate 21S is thinned by grinding, for example. Thus, the first piezoelectric film 21 is formed. The second principal surface 21b of the first piezoelectric film 21 is smoothed by polishing, for example.

In the lower electrode forming process (step S13), the lower electrode 32 is formed into a pattern on the second principal surface 21b of the first piezoelectric film 21 in accordance with a lift-off method or the like, for example. In this instance, a not-illustrated metallic film for routing wiring and the like is also formed on the second principal surface 21b of the first piezoelectric film 21.

In the sacrificial layer forming process (step S14), a sacrificial layer 13S is formed on the second principal surface 21b of the first piezoelectric film 21 so as to partially cover the lower electrode 32. The sacrificial layer 13S is made of zinc oxide, for example.

In the intermediate layer forming process (step S15), an insulating body is formed on the second principal surface 21b of the first piezoelectric film 21 so as to cover the lower electrode 32 and the sacrificial layer 13S. Moreover, the intermediate layer 12 made of the insulating body is formed by, for example, flattening and smoothing a surface on the opposite side from the first piezoelectric film 21.

In the joining process (step S16), the first piezoelectric film 21, the lower electrode 32, and the like are joined to the support 10 by the intermediate layer 12. Thereafter, the transfer substrate WT is removed from the first piezoelectric film 21.

In the second piezoelectric material substrate bonding process (step S17), a second piezoelectric material substrate 22S being the unprocessed second piezoelectric film 22 is bonded to the first principal surface 21a of the first piezoelectric film 21.

In the second piezoelectric material substrate thinning process (step S18), the second piezoelectric material substrate 22S is thinned by grinding, for example. Thus, the second piezoelectric film 22 is formed. The third principal surface 22a of the second piezoelectric film 22 is smoothed by polishing, for example. In the present example embodiment, the second piezoelectric film 22 is ground into the same or substantially the same thickness as that of the first piezoelectric film 21.

In the upper electrode forming process (step S19), the upper electrode 31 is formed on the third principal surface 22a of the second piezoelectric film 22. In the present example embodiment, the upper electrode 31 is formed in accordance with the lift-off method, for example. In this instance, a metallic film for wiring and the like may be formed on the third principal surface 22a of the second piezoelectric film 22 at the same time. Meanwhile, a layer made of an insulating body such as a protection film, for example, may be provided after forming the upper electrode 31.

In the piezoelectric layer window opening process (step S20), the window is opened in the piezoelectric layer 20. In the present example embodiment, the open window 20W and a not-illustrated through-hole are formed by providing a resist pattern and performing dry etching, for example.

In the void portion forming process (step S21), the sacrificial layer 13S is removed by introducing, for example, an etching gas or an etchant into the not-illustrated through hole, thus forming the void portion 13.

The support 10 is divided into individual pieces subsequent to the above-described processes. In the example embodiment of FIG. 8, the support 10 is divided into the individual pieces by removing a portion in a region between a dash-dot line D1 and a dash-dot line D2 where the functional electrodes (the upper electrode 31 and the lower electrode 32) are absent. In this way, it is possible to manufacture the piezoelectric device 1 according to the present example embodiment. The above-described processes are mere schematic representation and can be modified as appropriate.

Examples according to example embodiments of the present invention will be described below. Table 1 illustrates the examples according to the present example embodiment.

TABLE 1

| | PIEZOELECTRIC | | φ₂ | φ₃ | θ₁ | θ₂ | θ₃ | d | w |
|---|---|---|---|---|---|---|---|---|---|
| EXAMPLE | BODY | CUT ANGLE | (°) | (°) | (°) | (°) | (°) | (μm) | (μm) |
| EXAMPLE 1 | LiNbO₃ | 10° Y-CUT | 38 | 76 | 20 | 67 | 20 | 1 | 50 |
| EXAMPLE 2 | LiTaO₃ | 40° Y-CUT | 42 | 84 | 0 | 84 | 0 | 0.5 | 100 |
| EXAMPLE 3 | LiTaO₃ | 40° Y-CUT | 42 | 84 | 0 | 84 | 0 | 2 | 18 |
| EXAMPLE 4 | LiTaO₃ | 38.5° Y- | 42 | 86 | 2 | 86 | 2 | 0.5 | 50 |
| | | CUT | | | | | | | |
| EXAMPLE 5 | LiTaO₃ | 38.5° Y- | 42 | 86 | 2 | 86 | 2 | 0.2 | 25 |
| | | CUT | | | | | | | |
| EXAMPLE 6 | LiNbO₃ | 40° Y-CUT | 44 | 88 | 1 | 83 | 1 | 1 | 50 |

In Examples 1 to 6, the first piezoelectric film and the second piezoelectric film each include a first cleavage surface, a second cleavage surface, and a third cleavage surface which are cleavage surfaces extending in three directions. Here, the first piezoelectric film and the second piezoelectric film include the same material, the same crystal orientation, and the same thickness. The azimuthal angles and the inclination angles of the respective cleavage surfaces are therefore equal or substantially equal. Accordingly, the azimuthal angle of the second cleavage surfaces of the first piezoelectric film and the second piezoelectric film will be explained as an azimuthal angle φ₂ (=φ₁₂=φ₂₂) of the second cleavage surface, the azimuthal angle of the third cleavage surfaces of the first piezoelectric film and the second piezoelectric film will be explained as an azimuthal angle φ₃ (=φ₁₃=φ₂₃) of the third cleavage surface, the inclination angle of the first cleavage surfaces of the first piezoelectric film and the second piezoelectric film will be explained as an inclination angle θ₁ (=θ₁₁=θ₂₁) of the first cleavage surface, the inclination angle of the second cleavage surfaces of the first piezoelectric film and the second piezoelectric film will be explained as an inclination angle θ₂ (=θ₁₂=θ₂₂) of the second cleavage surface, and the inclination angle of the third cleavage surfaces of the first piezoelectric film and the second piezoelectric film will be explained as an inclination angle θ₃ (=θ₁₃=θ₂₃) of the third cleavage surface in Table 1 and in the following description.

In Examples 1 to 6, the thickness of the first piezoelectric film and the thickness of the second piezoelectric film will be explained as a value d. In Examples 1 to 6, the shape of the void portion 13 in plan view in the V direction is a circle with the diameter w. Accordingly, if the inclination angle θ of the cleavage surface satisfies the following formula (2), then the specific cleavage surface parallel or substantially parallel to the direction of the cleavage surface is present:

$$tan θ = w / d . \qquad ( 2 )$$

In Example 1, the first piezoelectric film and the second piezoelectric film were each made of a 10° Y-cut ((0, −80, 0) when expressed in the Euler angles) LiNbO₃ single crystal. In 10° Y-cut LiNbO₃, the azimuthal angle φ₂ of the second cleavage surface is equal to about 38°, the azimuthal angle φ₃ of the third cleavage surface is equal to about 76°, the inclination angle θ₁ of the first cleavage surface is equal to about 20°, the inclination angle θ₂ of the second cleavage surface is equal to about 67°, and the inclination angle θ₃ of the third cleavage surface is equal to about 20°.

Meanwhile, in Example 1, the diameter w of the void portion is equal to about 50 μm and the value d of the thickness of the first piezoelectric film and the thickness of the second piezoelectric film is equal to about 1 μm. Accordingly, w/d=about 50 is satisfied. Thus, tan θ₁=tan θ₃=about 0.364 and tan θ₂=about 2.356 are satisfied and tan θ₁=tan θ₃<tan θ₂<w/d therefore is satisfied. As a consequence, the specific cleavage surfaces parallel or substantially parallel to the first cleavage surface, the second cleavage surface, and the third cleavage surface are present.

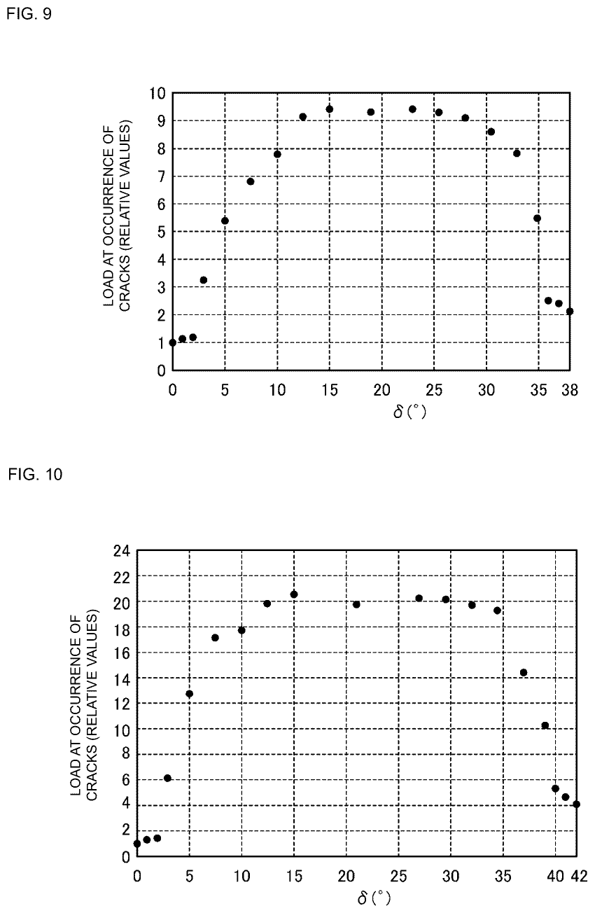

Table 2 shows a relationship between the relative azimuthal angle δ and the magnitude of load at the occurrence of cracks according to Example 1. FIG. 9 is a diagram showing the relationship between the relative azimuthal angle δ and the magnitude of load at the occurrence of cracks according to Example 1. Here, FIG. 9 is a graph plotting relative azimuthal angles δ and magnitude of load at the occurrence of cracks in Table 2. The magnitude of load at the occurrence of cracks means the magnitude of load when cracks occur as a consequence of application of the load to the piezoelectric layer, which is expressed by a relative value to a value in the case where the relative azimuthal angle δ is equal to about 0° in FIG. 9. That is to say, the larger the magnitude of load at the occurrence of cracks is, it is less likely that cracks would occur in the piezoelectric layer.

TABLE 2

| | MINIMUM | LOAD AT OCCURRENCE OF |
|---|---|---|
| | AZIMUTHAL ANGLE | CRACKS (RELATIVE |
| δ (°) | (°) | VALUES) |
| 0 | 0 | 1 |
| 1 | 1 | 1.1 |
| 2 | 2 | 1.2 |
| 3 | 3 | 3.2 |
| 5 | 5 | 5.4 |
| 7.5 | 7.5 | 6.8 |
| 10 | 10 | 7.8 |
| 12.5 | 12.5 | 9.1 |
| 15 | 15 | 9.4 |
| 19 | 19 | 9.3 |
| 23 | 15 | 9.4 |
| 25.5 | 12.5 | 9.3 |
| 28 | 10 | 9.1 |
| 30.5 | 7.5 | 8.6 |
| 33 | 5 | 7.8 |
| 35 | 3 | 5.5 |
| 36 | 2 | 2.5 |
| 37 | 1 | 2.4 |
| 38 | 0 | 2.1 |

As shown in Table 2, in Example 1, both of the azimuthal angle φ₂ of the second cleavage surface and an angle φ₃-φ₂ between the second cleavage surface and the third cleavage surface are equal to about 38°. Accordingly, when the relative azimuthal angle δ is equal to or greater than about 0° and equal to or less than about 19°, the minimum azimuthal angle is equal to the relative azimuthal angle δ. On the other hand, when the relative azimuthal angle δ is greater than about 19° and equal to or less than about 38°, the minimum azimuthal angle is equal to about 38°−δ.

As shown in Table 2 and FIG. 9, in the case where about 0°<δ≤about 38° is satisfied, that is to say, in the case where at least one cleavage surface among the cleavage surfaces of the first piezoelectric film, and at least one cleavage surface among the cleavage surfaces of the second piezoelectric film extend in the intersecting directions, cracks in the piezoelectric layer can be reduced or prevented because the magnitude of the load at the occurrence of cracks is larger than that in the case where δ=about 0° is satisfied, that is to say, in the case where all of the cleavage surfaces of the first piezoelectric film and all of the cleavage surfaces of the second piezoelectric film extend in the same or substantially the same direction.

As shown in Table 2 and FIG. 9, in the case where about 0°<δ≤about 38° is satisfied, that is to say, in the case where the first cleavage surface and the third cleavage surface having the smallest inclination angle among the cleavage surfaces of the first piezoelectric film, and the first cleavage surface and the third cleavage surface having the smallest inclination angle among the cleavage surfaces of the second piezoelectric film extend in the intersecting directions, cracks in the piezoelectric layer can be reduced or prevented because the magnitude of the load at the occurrence of cracks is larger than that in the case where δ=about 0° is satisfied, that is to say, in the case where all of the first cleavage surface and the third cleavage surface having the smallest inclination angle among the cleavage surfaces of the first piezoelectric film, and all of the first cleavage surface and the third cleavage surface having the smallest inclination angle among the cleavage surfaces of the second piezoelectric film extend in the same or substantially the same direction.

As shown in Table 2 and FIG. 9, in the case where about 0°<δ≤about 38° is satisfied, that is to say, in the case where at least one cleavage surface among the first cleavage surface, the second cleavage surface, and the third cleavage surface of the first piezoelectric film in which the parallel or substantially parallel specific cleavage surface is present, and at least one cleavage surface among the first cleavage surface, the second cleavage surface, and the third cleavage surface of the second piezoelectric film in which the parallel or substantially parallel specific cleavage surface is present extend in the intersecting directions, cracks in the piezoelectric layer can be reduced or prevented because the magnitude of the load at the occurrence of cracks is larger than that in the case where δ=about 0° is satisfied, that is to say, in the case where the first cleavage surface, the second cleavage surface, and the third cleavage surface of the first piezoelectric film in which the parallel or substantially parallel specific cleavage surface is present, and the first cleavage surface, the second cleavage surface, and the third cleavage surface of the second piezoelectric film in which the parallel or substantially parallel specific cleavage surface is present extend in the same or substantially the same direction.

As shown in Table 2 and FIG. 9, in the case where δ=about 19° is satisfied, that is to say, in the case where at least piezoelectric film extends in the same or substantially the same direction as the bisector of the angle between two cleavage surfaces of the second piezoelectric film intersecting with each other in plan view in the V direction, and at least one cleavage surface among the cleavage surfaces of the second piezoelectric film extends in the same or substantially the same direction as the bisector of the angle between two cleavage surfaces of the first piezoelectric film intersecting with each other in plan view in the V direction, cracks in the piezoelectric layer can be reduced or prevented because the magnitude of the load at the occurrence of cracks is larger than that in the case where about 0°≤δ<about 19° or about 19°<δ≤about 38° is satisfied, that is to say, in the case where at least one cleavage surface among the cleavage surfaces of the first piezoelectric film extends in the direction intersecting with the bisector of the angle between two cleavage surfaces of the second piezoelectric film intersecting with each other in plan view in the V direction, and at least one cleavage surface among the cleavage surfaces of the second piezoelectric film extends in the direction intersecting with the bisector of the angle between two cleavage surfaces of the first piezoelectric film intersecting with each other in plan view in the V direction.

As shown in Table 2 and FIG. 9, in the case where about 0°<δ<about 38° is satisfied, that is to say, in the case where the cleavage surfaces of the first piezoelectric film and all of the cleavage surfaces of the second piezoelectric film extend in the intersecting directions, cracks in the piezoelectric layer can be reduced or prevented because the magnitude of the load at the occurrence of cracks is larger than that in the case where δ=about 0° or δ=about 38° is satisfied, that is to say, in the case where at least one cleavage surface among the cleavage surfaces of the first piezoelectric film and at least one cleavage surface among the cleavage surfaces of the second piezoelectric film extend in the same or substantially the same direction.

As shown in Table 2 and FIG. 9, in the case where about 3°≤δ≤about 35° is satisfied, that is to say, in the case where the magnitude of the smallest angle between the cleavage surface of the first piezoelectric film and the cleavage surface of the second piezoelectric film is equal to or greater than about 3°, cracks in the piezoelectric layer can be reduced or prevented more appropriately because the magnitude of the load at the occurrence of cracks is larger than that in the case where about 0°≤δ<about 3° or about 35°<δ≤about 38° is satisfied, that is to say, in the case where the magnitude of the smallest angle between the cleavage surface of the first piezoelectric film and the cleavage surface of the second piezoelectric film is below about 3°.

As shown in Table 2 and FIG. 9, in the case where about 12.5°≤δ≤about 25.5° is satisfied, that is to say, in the case where the magnitude of the smallest angle between the cleavage surface of the first piezoelectric film and the cleavage surface of the second piezoelectric film is equal to or greater than about 12.5°, cracks in the piezoelectric layer can be reduced or prevented even more appropriately because the magnitude of the load at the occurrence of cracks is larger than that in the case where about 0°≤δ<about 12.5° or about 25.5°<δ≤about 38° is satisfied, that is to say, in the case where the magnitude of the smallest angle between the cleavage surface of the first piezoelectric film and the cleavage surface of the second piezoelectric film is below about 12.5°.

In Example 2, the first piezoelectric film and the second piezoelectric film were each made of a 40° Y-cut ((0, −50, 0) when expressed in the Euler angles) LiTaO₃ single crystal. In 40° Y-cut LiTaO₃, the azimuthal angle φ₂ of the second cleavage surface is equal to about 42°, the azimuthal angle φ₃ of the third cleavage surface is equal to about 84°, the inclination angle θ₁ of the first cleavage surface is equal to about 0°, the inclination angle θ₂ of the second cleavage surface is equal to about 84°, and the inclination angle θ₃ of the third cleavage surface is equal to about 0°.

Meanwhile, in Example 2, the diameter w of the void portion is equal to about 100 μm and the value d of the thickness of the first piezoelectric film and the thickness of the second piezoelectric film is equal to about 0.5 μm. Accordingly, w/d=about 200 is satisfied. Thus, tan θ₁=tan θ₃=0.000 and tan θ2=about 9.514 hold true and tan θ₁=tan θ₃<tan θ₂<w/d therefore is satisfied. As a consequence, the specific cleavage surfaces parallel or substantially parallel to the first cleavage surface, the second cleavage surface, and the third cleavage surface are present.

Table 3 is a table showing a relationship between the relative azimuthal angle δ and the magnitude of load at the occurrence of cracks according to Example 2. FIG. 10 is a diagram showing the relationship between the relative azimuthal angle δ and the magnitude of load at the occurrence of cracks according to Example 2. Here, FIG. 10 is a graph plotting relative azimuthal angles δ and the magnitude of load at the occurrence of cracks in Table 3. In FIG. 10, the magnitude of load at the occurrence of cracks is expressed by a relative value to a value in the case where the relative azimuthal angle δ is equal to about 0° as with FIG. 9.

TABLE 3

| | MINIMUM | LOAD AT OCCURRENCE OF |
|---|---|---|
| | AZIMUTHAL ANGLE | CRACKS (RELATIVE |
| δ (°) | (°) | VALUES) |
| 0 | 0 | 1 |
| 1 | 1 | 1.3 |
| 2 | 2 | 1.4 |
| 3 | 3 | 6.1 |
| 5 | 5 | 12.7 |
| 7.5 | 7.5 | 17.1 |
| 10 | 10 | 17.9 |
| 12.5 | 12.5 | 19.8 |
| 15 | 15 | 20.5 |
| 21 | 21 | 19.9 |
| 27 | 15 | 20.2 |
| 29.5 | 12.5 | 20.1 |
| 32 | 10 | 19.7 |
| 34.5 | 7.5 | 19.3 |
| 37 | 5 | 14.4 |
| 39 | 3 | 10.2 |
| 40 | 2 | 5.3 |
| 41 | 1 | 4.6 |
| 42 | 0 | 4.1 |

As shown in Table 3, in Example 2, both of the azimuthal angle φ₂ of the second cleavage surface and the angle φ₃-φ₂ between the second cleavage surface and the third cleavage surface are equal to about 42°. Accordingly, when the relative azimuthal angle δ is equal to or greater than about 0° and equal to or less than about 21°, the minimum azimuthal angle is equal to the relative azimuthal angle δ. On the other hand, when the relative azimuthal angle δ is greater than about 21° and equal to or less than about 42°, the minimum azimuthal angle is equal to about 42°−δ.

As shown in Table 3 and FIG. 10, in the case where about 0°<δ≤about 42° is satisfied, that is to say, in the case where at least one cleavage surface among the cleavage surfaces of the first piezoelectric film, and at least one cleavage surface among the cleavage surfaces of the second piezoelectric film extend in the intersecting directions, cracks in the piezoelectric layer can be reduced or prevented because the magnitude of the load at the occurrence of cracks is larger than that in the case where δ=about 0° is satisfied, that is to say, in the case where all of the cleavage surfaces of the first piezoelectric film and all of the cleavage surfaces of the second piezoelectric film extend in the same or substantially the same direction.

As shown in Table 3 and FIG. 10, in the case where about 0°<δ≤about 42° is satisfied, that is to say, in the case where the first cleavage surface and the third cleavage surface having the smallest inclination angle among the cleavage surfaces of the first piezoelectric film, and the first cleavage surface and the third cleavage surface having the smallest inclination angle among the cleavage surfaces of the second piezoelectric film extend in the intersecting directions, cracks in the piezoelectric layer can be reduced or prevented because the magnitude of the load at the occurrence of cracks is larger than that in the case where δ=about 0° is satisfied, that is to say, in the case where all of the first cleavage surface and the third cleavage surface having the smallest inclination angle among the cleavage surfaces of the first piezoelectric film, and all of the first cleavage surface and the third cleavage surface having the smallest inclination angle among the cleavage surfaces of the second piezoelectric film extend in the same or substantially the same direction.

As shown in Table 3 and FIG. 10, in the case where about 0°<δ≤about 42° is satisfied, that is to say, in the case where at least one cleavage surface among the first cleavage surface, the second cleavage surface, and the third cleavage surface of the first piezoelectric film in which the parallel or substantially parallel specific cleavage surface is present, and at least one cleavage surface among the first cleavage surface, the second cleavage surface, and the third cleavage surface of the second piezoelectric film in which the parallel or substantially parallel specific cleavage surface is present extend in the intersecting directions, cracks in the piezoelectric layer can be reduced or prevented because the magnitude of the load at the occurrence of cracks is larger than that in the case where δ=about 0° is satisfied, that is to say, in the case where the first cleavage surface, the second cleavage surface, and the third cleavage surface of the first piezoelectric film in which the parallel or substantially parallel specific cleavage surface is present, and the first cleavage surface, the second cleavage surface, and the third cleavage surface of the second piezoelectric film in which the parallel or substantially parallel specific cleavage surface is present extend in the same or substantially the same direction.

As shown in Table 3 and FIG. 10, in the case where δ=about 21° is satisfied, that is to say, in the case where at least piezoelectric film extends in the same direction as the bisector of the angle between two cleavage surfaces of the second piezoelectric film intersecting with each other in plan view in the V direction, and at least one cleavage surface among the cleavage surfaces of the second piezoelectric film extends in the same direction as the bisector of the angle between two cleavage surfaces of the first piezoelectric film intersecting with each other in plan view in the V direction, cracks in the piezoelectric layer can be reduced or prevented because the magnitude of the load at the occurrence of cracks is larger than that in the case where about 0°≤δ<about 21° or about 21°<δ≤about 42° is satisfied, that is to say, in the case where at least one cleavage surface among the cleavage surfaces of the first piezoelectric film extends in the direction intersecting with the bisector of the angle between two cleavage surfaces of the second piezoelectric film intersecting with each other in plan view in the V direction, and at least one cleavage surface among the cleavage surfaces of the second piezoelectric film extends in the direction intersecting with the bisector of the angle between two cleavage surfaces of the first piezoelectric film intersecting with each other in plan view in the V direction.

As shown in Table 3 and FIG. 10, in the case where about 0°<δ<about 42° is satisfied, that is to say, in the case where the cleavage surfaces of the first piezoelectric film and all of the cleavage surfaces of the second piezoelectric film extend in the intersecting directions, cracks in the piezoelectric layer can be reduced or prevented because the magnitude of the load at the occurrence of cracks is larger than that in the case where δ=about 0° or δ=about 42° is satisfied, that is to say, in the case where at least one cleavage surface among the cleavage surfaces of the first piezoelectric film and at least one cleavage surface among the cleavage surfaces of the second piezoelectric film extend in the same or substantially the same direction.

As shown in Table 3 and FIG. 10, in the case where about 3°≤δ≤about 39° is satisfied, that is to say, in the case where the magnitude of the smallest angle between the cleavage surface of the first piezoelectric film and the cleavage surface of the second piezoelectric film is equal to or greater than about 3°, cracks in the piezoelectric layer can be reduced or prevented more appropriately because the magnitude of the load at the occurrence of cracks is larger than that in the case where about 0°≤δ<about 3° or about 39°<δ≤about 42° is satisfied, that is to say, in the case where the magnitude of the smallest angle between the cleavage surface of the first piezoelectric film and the cleavage surface of the second piezoelectric film is less than about 3°.

As shown in Table 3 and FIG. 10, in the case where about 12.5°≤δ≤about 29.5° is satisfied, that is to say, in the case where the magnitude of the smallest angle between the cleavage surface of the first piezoelectric film and the cleavage surface of the second piezoelectric film is equal to or greater than about 12.5°, cracks in the piezoelectric layer can be reduced or prevented even more appropriately because the magnitude of the load at the occurrence of cracks is larger than that in the case where about 0°≤δ<about 12.5° or about 29.5°<δ≤about 42° is satisfied, that is to say, in the case where the magnitude of the smallest angle between the cleavage surface of the first piezoelectric film and the cleavage surface of the second piezoelectric film is less than about 12.5°.

In Example 3, the first piezoelectric film and the second piezoelectric film were each made of a 40° Y-cut LiTaO₃ single crystal as with Example 2. In Example 3, the diameter w of the void portion is equal to about 18 μm and the value d of the thickness of the first piezoelectric film and the thickness of the second piezoelectric film is equal to about 2 μm. Accordingly, w/d=about 9 is satisfied. Thus, tan θ₁=tan θ3=about 0.000 and tan θ2=about 9.514 are satisfied and tan θ₁=tan θ₃<w/d<tan θ₂ therefore is satisfied. As a consequence, the specific cleavage surfaces parallel or substantially parallel to the first cleavage surface and the third cleavage surface are present.

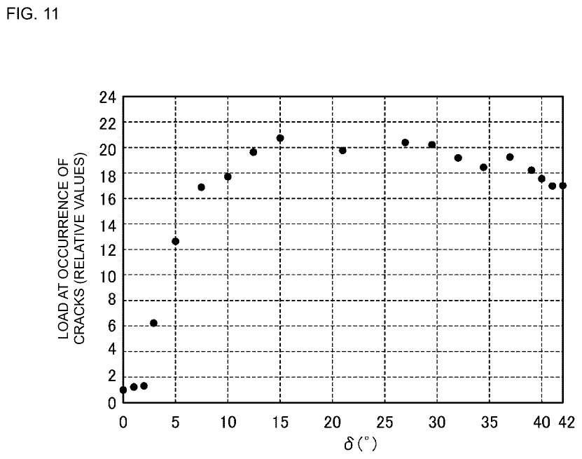

Table 4 is a table showing a relationship between the relative azimuthal angle δ and the magnitude of load at the occurrence of cracks according to Example 3. FIG. 11 is a diagram showing the relationship between the relative azimuthal angle δ and the magnitude of load at the occurrence of cracks according to Example 3. Here, FIG. 11 is a graph plotting relative azimuthal angles δ and magnitude of load at the occurrence of cracks in Table 4. In FIG. 11, the magnitude of load at the occurrence of cracks is expressed by a relative value to a value in the case where the relative azimuthal angle δ is equal to about 0° as with FIG. 9.

TABLE 4

| | MINIMUM | LOAD AT OCCURRENCE OF |
|---|---|---|
| | AZIMUTHAL ANGLE | CRACKS (RELATIVE |
| δ (°) | (°) | VALUES) |
| 0 | 0 | 1 |
| 1 | 1 | 1.3 |
| 2 | 2 | 1.4 |
| 3 | 3 | 6.1 |
| 5 | 5 | 12.7 |
| 7.5 | 7.5 | 17.1 |
| 10 | 10 | 17.9 |
| 12.5 | 12.5 | 19.8 |
| 15 | 15 | 20.5 |
| 21 | 21 | 19.9 |
| 27 | 15 | 20.2 |
| 29.5 | 12.5 | 20.1 |
| 32 | 10 | 19.7 |
| 34.5 | 7.5 | 19.3 |
| 37 | 5 | 19.6 |
| 39 | 3 | 19.2 |
| 40 | 2 | 18.7 |
| 41 | 1 | 17.9 |
| 42 | 0 | 17.9 |

As shown in Table 4, in Example 3, both of the azimuthal angle φ₂ of the second cleavage surface and the angle φ₃-φ₂ between the second cleavage surface and the third cleavage surface are equal to about 42°. Accordingly, when the relative azimuthal angle δ is equal to or greater than about 0° and equal to or less than about 21°, the minimum azimuthal angle is equal to the relative azimuthal angle δ. On the other hand, when the relative azimuthal angle δ is above 21° and equal to or less than about 42°, the minimum azimuthal angle is equal to about 42°−δ.

As shown in Table 4 and FIG. 11, in the case where about 0°<δ≤about 42° is satisfied, that is to say, in the case where at least one cleavage surface among the cleavage surfaces of the first piezoelectric film, and at least one cleavage surface among the cleavage surfaces of the second piezoelectric film extend in the intersecting directions, cracks in the piezoelectric layer can be reduced or prevented because the magnitude of the load at the occurrence of cracks is larger than that in the case where δ=about 0° is satisfied, that is to say, in the case where all of the cleavage surfaces of the first piezoelectric film and all of the cleavage surfaces of the second piezoelectric film extend in the same direction.

As shown in Table 4 and FIG. 11, in the case where about 0°<δ≤about 42° is satisfied, that is to say, in the case where the first cleavage surface and the third cleavage surface having the smallest inclination angle among the cleavage surfaces of the first piezoelectric film, and the first cleavage surface and the third cleavage surface having the smallest inclination angle among the cleavage surfaces of the second piezoelectric film extend in the intersecting directions, cracks in the piezoelectric layer can be reduced or prevented because the magnitude of the load at the occurrence of cracks is larger than that in the case where δ=about 0° is satisfied, that is to say, in the case where all of the first cleavage surface and the third cleavage surface having the smallest inclination angle among the cleavage surfaces of the first piezoelectric film, and all of the first cleavage surface and the third cleavage surface having the smallest inclination angle among the cleavage surfaces of the second piezoelectric film extend in the same or substantially the same direction.

As shown in Table 4 and FIG. 11, in the case where about 0°<δ≤about 42° is satisfied, that is to say, in the case where at least one cleavage surface of the first cleavage surface and the third cleavage surface of the first piezoelectric film in which the parallel or substantially parallel specific cleavage surface is present, and at least one cleavage surface of the first cleavage surface and the third cleavage surface of the second piezoelectric film in which the parallel or substantially parallel specific cleavage surface is present extend in the intersecting directions, cracks in the piezoelectric layer can be reduced or prevented because the magnitude of the load at the occurrence of cracks is larger than that in the case where δ=about 0° is satisfied, that is to say, in the case where the first cleavage surface as well as the third cleavage surface of the first piezoelectric film in which the parallel or substantially parallel specific cleavage surface is present, and the first cleavage surface as well as the third cleavage surface of the second piezoelectric film in which the parallel or substantially parallel specific cleavage surface is present extend in the same or substantially the same direction.

As shown in Table 4 and FIG. 11, in the case where δ=about 21° is satisfied, that is to say, in the case where at least piezoelectric film extends in the same or substantially the same direction as the bisector of the angle between two cleavage surfaces of the second piezoelectric film intersecting with each other in plan view in the V direction, and at least one cleavage surface among the cleavage surfaces of the second piezoelectric film extends in the same or substantially the same direction as the bisector of the angle between two cleavage surfaces of the first piezoelectric film intersecting with each other in plan view in the V direction, cracks in the piezoelectric layer can be reduced or prevented because the magnitude of the load at the occurrence of cracks is larger than that in the case where about 0°≤δ<about 21° or about 21°<δ≤about 42° is satisfied, that is to say, in the case where at least one cleavage surface among the cleavage surfaces of the first piezoelectric film extends in the direction intersecting with the bisector of the angle between two cleavage surfaces of the second piezoelectric film intersecting with each other in plan view in the V direction, and at least one cleavage surface among the cleavage surfaces of the second piezoelectric film extends in the direction intersecting with the bisector of the angle between two cleavage surfaces of the first piezoelectric film intersecting with each other in plan view in the V direction.

As shown in Table 4 and FIG. 11, in the case where about 0°<δ<about 42° is satisfied, that is to say, in the case where the cleavage surfaces of the first piezoelectric film and all of the cleavage surfaces of the second piezoelectric film extend in the intersecting directions, cracks in the piezoelectric layer can be reduced or prevented because the magnitude of the load at the occurrence of cracks is larger than that in the case where δ=about 0° or δ=about 42° is satisfied, that is to say, in the case where at least one cleavage surface among the cleavage surfaces of the first piezoelectric film and at least one cleavage surface among the cleavage surfaces of the second piezoelectric film extend in the same or substantially the same direction.

As shown in Table 4 and FIG. 11, in the case where about 3°≤δ≤about 39° is satisfied, that is to say, in the case where the magnitude of the smallest angle between the cleavage surface of the first piezoelectric film and the cleavage surface of the second piezoelectric film is equal to or greater than about 3°, cracks in the piezoelectric layer can be reduced or prevented more appropriately because the magnitude of the load at the occurrence of cracks is larger than that in the case where about 0°≤δ<about 3° or about 39°<δ≤about 42° is satisfied, that is to say, in the case where the magnitude of the smallest angle between the cleavage surface of the first piezoelectric film and the cleavage surface of the second piezoelectric film is less than about 3°.

As shown in Table 4 and FIG. 11, in the case where about 12.5°<δ<about 29.5° is satisfied, that is to say, in the case where the magnitude of the smallest angle between the cleavage surface of the first piezoelectric film and the cleavage surface of the second piezoelectric film is equal to or greater than about 12.5°, cracks in the piezoelectric layer can be reduced or prevented even more appropriately because the magnitude of the load at the occurrence of cracks is larger than that in the case where about 0°≤δ<about 12.5° or about 29.5°<δ≤about 42° is satisfied, that is to say, in the case where the magnitude of the smallest angle between the cleavage surface of the first piezoelectric film and the cleavage surface of the second piezoelectric film is less than about 12.5°.

In Example 4, the first piezoelectric film and the second piezoelectric film were each made of a 38.5° Y-cut ((0, −51.5, 0) when expressed in the Euler angles) LiTaO₃ single crystal. In 38.5° Y-cut LiTaO₃, the azimuthal angle φ₂ of the second cleavage surface is equal to about 42°, the azimuthal angle φ₃ of the third cleavage surface is equal to about 86°, the inclination angle θ₁ of the first cleavage surface is equal to about 2°, the inclination angle θ₂ of the second cleavage surface is equal to about 86°, and the inclination angle θ₃ of the third cleavage surface is equal to about 2°.

Meanwhile, in Example 4, the diameter w of the void portion is equal to about 50 μm and the value d of the thickness of the first piezoelectric film and the thickness of the second piezoelectric film is equal to about 0.5 μm. Accordingly, w/d=about 100 is satisfied. Thus, tan θ1=tan θ₃=about 0.000 and tan θ₂=about 14.301 are satisfied and tan θ1=tan θ3<tan θ₂<w/d therefore is satisfied. As a consequence, the specific cleavage surfaces parallel or substantially parallel to the first cleavage surface, the second cleavage surface, and the third cleavage surface are present.

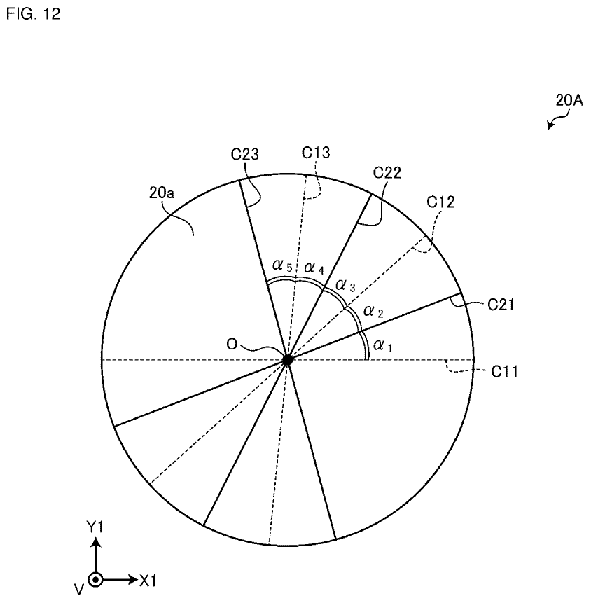

FIG. 12 is a schematic plan view for explaining positions of the cleavage surfaces according to Example 4. In Example 4, the relative azimuthal angle δ is equal to about 21°. In Example 4, both the azimuthal angle φ₂ of the second cleavage surface C12 or C22 and the angle φ₃-φ₂ between the second cleavage surface C12 or C22 and the third cleavage surface C13 or C23 are equal to about 42°.

In Example 4, an angle α₁ between the first cleavage surface C11 of the first piezoelectric film and the first cleavage surface C21 of the second piezoelectric film, an angle α₂ between the first cleavage surface C21 of the second piezoelectric film and the second cleavage surface C12 of the first piezoelectric film, an angle α₃ between the second cleavage surface C12 of the first piezoelectric film and the second cleavage surface C22 of the second piezoelectric film, an angle α₄ between the second cleavage surface C22 of the second piezoelectric film and the third cleavage surface C13 of the first piezoelectric film, and an angle α₅ between the third cleavage C13 surface 41 of the first piezoelectric film and the third cleavage surface C23 of the second piezoelectric film are all equal to about 21°. In other words, the first cleavage surface C21 of the second piezoelectric film extends in the same or substantially the same direction as the bisector of the angle between the cleavage surfaces C11 and C12 of the first piezoelectric film, the second cleavage surface C12 of the first piezoelectric film extends in the same or substantially the same direction as the bisector of the angle between the cleavage surfaces C21 and C22 of the second piezoelectric film, the second cleavage surface C22 of the second piezoelectric film extends in the same or substantially the same direction as the bisector of the angle between the cleavage surfaces C12 and C13 of the first piezoelectric film, and the third cleavage surface C13 of the first piezoelectric film extends in the same or substantially the same direction as the bisector of the angle between the cleavage surfaces C22 and C23 of the second piezoelectric film. In this case, cracks in the piezoelectric layer can be reduced or prevented more appropriately.

In Example 4, the first cleavage surface and the third cleavage surface having the smallest inclination angle among the cleavage surfaces of the first piezoelectric film, and the first cleavage surface and the third cleavage surface having the smallest inclination angle among the cleavage surfaces of the second piezoelectric film extend in the intersecting directions. Thus, cracks in the piezoelectric layer can be reduced or prevented.

In Example 4, at least one cleavage surface among the first cleavage surface, the second cleavage surface, and the third cleavage surface of the first piezoelectric film in which the parallel or substantially parallel specific cleavage surface is present, and at least one cleavage surface among the first cleavage surface, the second cleavage surface, and the third cleavage surface of the second piezoelectric film in which the parallel or substantially parallel specific cleavage surface is present extend in the intersecting directions. Thus, cracks in the piezoelectric layer can be reduced or prevented.

In Example 4, the cleavage surfaces of the first piezoelectric film and all of the cleavage surfaces of the second piezoelectric film extend in the intersecting directions. Accordingly, it is possible to reduce or prevent cracks in the piezoelectric layer.

In Example 5, the first piezoelectric film and the second piezoelectric film were each made of a 38.5° Y-cut LiTaO₃ single crystal. In 38.5° Y-cut LiTaO₃, the azimuthal angle φ₂ of the second cleavage surface is equal to about 42°, the azimuthal angle φ₃ of the third cleavage surface is equal to about 86°, the inclination angle θ₁ of the first cleavage surface is equal to about 2°, the inclination angle θ₂ of the second cleavage surface is equal to about 86°, and the inclination angle θ₃ of the third cleavage surface is equal to about 2°.

Meanwhile, in Example 5, the diameter w of the void portion is equal to about 25 μm and the value d of the thickness of the first piezoelectric film and the thickness of the second piezoelectric film is equal to about 0.2 μm. Accordingly, w/d=about 125 is satisfied. Thus, tan θ₁=tan θ₃=about 0.000 and tan θ₂=about 14.301 are satisfied and tan θ₁=tan θ₃<tan θ₂<w/d therefore is satisfied. As a consequence, the specific cleavage surfaces parallel or substantially parallel to the first cleavage surface, the second cleavage surface, and the third cleavage surface are present.

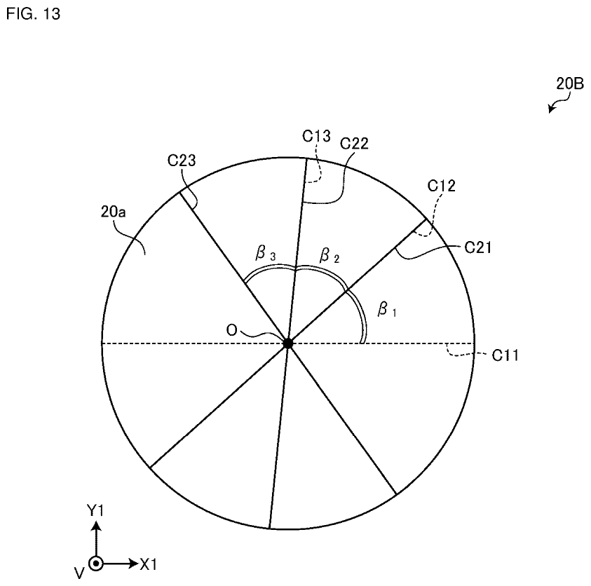

FIG. 13 is a schematic plan view for explaining positions of the cleavage surfaces according to Example 5. In Example 5, the relative azimuthal angle δ is equal to about 42°. In Example 5, both the azimuthal angle φ₂ of the second cleavage surface C12 or C22 and the angle φ₃-φ₂ between the second cleavage surface C12 or C22 and the third cleavage surface C13 or C23 are equal to about 42°.

In Example 5, an angle β₁ between the first cleavage surface C11 of the first piezoelectric film and the second cleavage surface C12 of the first piezoelectric film as well as the first cleavage surface C21 of the second piezoelectric film, an angle β₂ between the second cleavage surface C12 of the first piezoelectric film as well as the first cleavage surface C21 of the second piezoelectric film and the third cleavage surface C13 of the first piezoelectric film as well as the second cleavage surface C22 of the second piezoelectric film, and an angle β₃ between the third cleavage surface C13 of the first piezoelectric film as well as the second cleavage surface C22 of the second piezoelectric film and the third cleavage surface C23 of the second piezoelectric film are all equal to about 42°. In other words, the first cleavage surface C21 of the second piezoelectric film extends in the same or substantially the same direction as the bisector of the angle between the cleavage surfaces C11 and C13 of first piezoelectric film, and the third cleavage surface C13 of the first piezoelectric film extends in the same or substantially the same direction as the bisector of the angle between the cleavage surfaces C21 and C23 of the second piezoelectric film. In this case as well, cracks in the piezoelectric layer can be reduced or prevented more appropriately.

In Example 5, the first cleavage surface and the third cleavage surface having the smallest inclination angle among the cleavage surfaces of the first piezoelectric film, and the first cleavage surface and the third cleavage surface having the smallest inclination angle among the cleavage surfaces of the second piezoelectric film extend in the intersecting directions. Thus, cracks in the piezoelectric layer can be reduced or prevented.

In Example 5, at least one cleavage surface among the first cleavage surface, the second cleavage surface, and the third cleavage surface of the first piezoelectric film in which the parallel or substantially parallel specific cleavage surface is present, and at least one cleavage surface among the first cleavage surface, the second cleavage surface, and the third cleavage surface of the second piezoelectric film in which the parallel or substantially parallel specific cleavage surface is present extend in the intersecting directions. Thus, cracks in the piezoelectric layer can be reduced or prevented.

In Example 6, the first piezoelectric film and the second piezoelectric film were each made of a 40° Y-cut LiNbO₃ single crystal. In 40° Y-cut LiNbO₃, the azimuthal angle φ₂ of the second cleavage surface is equal to about 44°, the azimuthal angle φ₃ of the third cleavage surface is equal to about 88°, the inclination angle θ₁ of the first cleavage surface is equal to about 1°, the inclination angle θ₂ of the second cleavage surface is equal to about 83°, and the inclination angle θ₃ of the third cleavage surface is equal to about 1°. In this case as well, cracks in the piezoelectric layer can be reduced or prevented by adjusting the relative azimuthal angle δ in the same way as Examples 1 to 5 described above.

Meanwhile, in Example 6, the diameter w of the void portion is equal to about 50 μm and the value d of the thickness of the first piezoelectric film and the thickness of the second piezoelectric film is equal to about 1 μm. Accordingly, w/d=about 50 is satisfied. Thus, tan θ₁=tan θ₃=about 0.01745 and tan θ₂=about 8.14 are satisfied and tan θ₁=tan θ₃<tan θ₂<w/d therefore is satisfied. As a consequence, the specific cleavage surfaces parallel or substantially parallel to the first cleavage surface, the second cleavage surface, and the third cleavage surface are present.

The above-described example embodiments are intended to facilitate the understanding of the present invention and are not intended to limit the present invention in a restricted fashion. The present invention can be modified or improved without departing from the scope and gist thereof, and such equivalents are also included in the present invention.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a support including a support substrate;
a piezoelectric layer with a thickness in a first direction and provided on a principal surface of the support; and
a functional electrode on a principal surface of the piezoelectric layer; wherein
the piezoelectric layer includes:
a first piezoelectric film; and
a second piezoelectric film laminated on the first piezoelectric film;
the first piezoelectric film and the second piezoelectric film are each a single crystal made of a same material;
the first piezoelectric film and the second piezoelectric film have different polarization directions;
the first piezoelectric film and the second piezoelectric film each include cleavage surfaces; and
at least one cleavage surface among the cleavage surfaces of the first piezoelectric film, and at least one cleavage surface among the cleavage surfaces of the second piezoelectric film extend in intersecting directions in plan view in the first direction.

2. The piezoelectric device according to claim 1, wherein a cleavage surface among the cleavage surfaces of the first piezoelectric film that defines a smallest angle with the first direction and a cleavage surface among the cleavage surfaces of the second piezoelectric film that defines a smallest angle with the first direction extend in intersecting directions in plan view in the first direction.

3. The piezoelectric device according to claim 1, wherein the support includes a void at a position at least partially overlapping the piezoelectric layer in plan view in the first direction.

4. The piezoelectric device according to claim 3, wherein
the first piezoelectric film includes a first principal surface and a second principal surface;
the second piezoelectric film includes a third principal surface and a fourth principal surface; and
at least one cleavage surface among cleavage surfaces in which an intersection line with the first principal surface and an intersection line with the second principal surface pass through a region overlapping the void in plan view in the first direction among the cleavage surfaces of the first piezoelectric film, and at least one cleavage surface among cleavage surfaces in which an intersection line with the third principal surface and an intersection line with the fourth principal surface pass through a region overlapping the void in plan view in the first direction among the cleavage surfaces of the second piezoelectric film extend in intersecting directions.

5. The piezoelectric device according to claim 1, wherein all of the cleavage surfaces of the first piezoelectric film and all of the cleavage surfaces of the second piezoelectric film extend in intersecting directions in plan view in the first direction; and
a magnitude of a smallest angle between one of the cleavage surfaces of the first piezoelectric film and one of the cleavage surfaces of the second piezoelectric film is equal to or greater than about 12.5°.

6. The piezoelectric device according to claim 1, wherein the first piezoelectric film and the second piezoelectric film include LiTaO₃, LiNbO₃, or KNbO₃.

7. The piezoelectric device according to claim 1, wherein the support substrate includes silicon or quartz crystal.

8. The piezoelectric device according to claim 1, wherein the support includes an intermediate layer between the support substrate and the first piezoelectric film.

9. The piezoelectric device according to claim 8, wherein the intermediate layer includes silicon oxide.

10. The piezoelectric device according to claim 1, wherein all of the cleavage surfaces of the first piezoelectric film and all of the cleavage surfaces of the second piezoelectric film extend in intersecting directions in plan view in the first direction; and
a magnitude of a smallest angle between one of the cleavage surfaces of the first piezoelectric film and one of the cleavage surfaces of the second piezoelectric film is equal to or greater than about 3°.

11. The piezoelectric device according to claim 1, wherein thicknesses of the first and second piezoelectric films are equal or substantially equal.

12. The piezoelectric device according to claim 1, wherein the polarization direction of the first piezoelectric film and the polarization direction of the second piezoelectric film are opposite to each other.

13. The piezoelectric device according to claim 1, wherein a thickness of the piezoelectric layer is equal to or less than about 1 μm.

14. The piezoelectric device according to claim 1, wherein the piezoelectric film includes a through hole.

15. The piezoelectric device according to claim 3, wherein the void has a rectangular or substantially rectangular shape.
